(19) United States
(12) Patent Application Publication
(10) Pub. No.: US 2026/0146909 A1
(43) Pub. Date: May 28, 2026

(54) PRESSURE MEASURING DEVICE AND PRESSURE MEASURING SYSTEM

(71) Applicant: Samsung Electronics Co., Ltd., Suwon-si (KR)

(72) Inventors: Deokjin Kwon, Suwon-si (KR); JONGHWI KIM, Suwon-si (KR); Taejong Yu, Suwon-si (KR); HONGSEOK JANG, Suwon-si (KR); Donghoon Park, Suwon-si (KR); JUNGHYEON PARK, Suwon-si (KR); JIN SHIN, Suwon-si (KR)

(21) Appl. No.: 19/325,643

(22) Filed: Sep. 11, 2025

(30) Foreign Application Priority Data
Nov. 26, 2024 (KR) 10-2024-0171410

(51) Int. Cl. G01L 19/08; H01L 21/683

(52) U.S. Cl. CPC G01L 19/08; H10P 72/722

(57) ABSTRACT

A pressure measuring apparatus according to an embodiment may include a printed circuit board (PCB) substrate having a first surface facing an electrostatic chuck (ESC), the ESC having a plurality of ejection holes, and the PCB substrate including a plurality of penetration holes; a first cover disposed on a second surface of the PCB substrate, the first cover including a plurality of discharging holes provided at positions corresponding to the plurality of penetration holes; a second cover positioned between the PCB substrate and the ESC, the second cover including a plurality of flow paths connecting the plurality of ejection holes to the plurality of penetration holes; and a plurality of pressure sensors disposed between the PCB substrate and the second cover.

### CROSS-REFERENCE TO RELATED APPLICATION

This application claims priority to and the benefit of Korean Patent Application No. 10-2024-0171410 filed in the Korean Intellectual Property Office on Nov. 26, 2024, the entire contents of which are incorporated herein by reference.

### BACKGROUND OF THE DISCLOSURE

### Field of the Disclosure

The present disclosure relates to a pressure measuring apparatus and a pressure measurement system.

### Description of the Related Art

In a semiconductor manufacturing process, wafers may be processed using plasma in a vacuum chamber. At this time, an electrostatic chuck (ESC) that holds a wafer is a device that generates a voltage difference between the wafer and a metal electrode or electrode pair and chucks the wafer while the wafer and the electrode are separated by a dielectric layer.

The ESC is a device that uses an electrostatic force to hold the substrate flat, and a chucking method using the ESC may minimize damage generated in the wafer compared to a conventional chucking method that holds the wafer through physical contact.

The upper surface of the ESC is provided with holes at uniform intervals, and helium (He) is sprayed toward the wafer through these holes. When using plasma in a vacuum state, the temperature of the wafer rises significantly, so a process to stabilize the temperature of the wafer is desirable. This is because the local temperature rise in the wafer may occur, which may damage the wafer.

However, as the process progresses, process by-products may block the holes in the ESC, causing a clogging phenomenon in which helium cannot be properly injected. Previously, the clogging of the hole that injects helium from the ESC was determined through an indirect method, or the damage level of the helium hole was confirmed by cutting the ESC.

However, the conventional method had the problem that it was impossible to check whether the hole was blocked while the process was in progress and the ESC was mounted on the equipment, and it was impossible to specify the position of the hole where the defect occurred.

### SUMMARY OF THE DISCLOSURE

Embodiments of the present disclosure are proposed to solve the above problems, and the present disclosure provides a pressure measuring apparatus and a pressure measurement system that utilize a pressure measuring apparatus that measures the pressure of gas ejected from the ESC, and can directly determine whether each ejection hole is blocked by measuring the pressure of gas ejected through a plurality of ejection holes. However, the inventive concept is not limited thereto.

In addition, the pressure measuring apparatus may be placed on the ESC surface mounted on an equipment to measure a pressure, thereby the present disclosure aims to provide a pressure measuring apparatus and a pressure measurement system that may determine whether the ejection hole is blocked even during the process.

In addition, a pressure sensor may be arranged in the plurality of ejection holes so as to measure the pressure of gas ejected from each ejection hole, thereby a pressure measuring apparatus and a pressure measurement system capable of analyzing the measured pressure value to identify the position of the ejection hole where a defect has occurred are provided.

A pressure measuring apparatus according to an embodiment may include a printed circuit board (PCB) substrate having a first surface facing an electrostatic chuck (ESC), the ESC having a plurality of ejection holes, and the PCB substrate including a plurality of penetration holes; a first cover disposed on a second surface of the PCB substrate, the first cover including a plurality of discharging holes provided at positions corresponding to the plurality of penetration holes; a second cover positioned between the PCB substrate and the ESC, the second cover including a plurality of flow paths connecting the plurality of ejection holes to the plurality of penetration holes; and a plurality of pressure sensors disposed between the PCB substrate and the second cover.

A pressure measuring apparatus according to an embodiment may be disposed on an ESC, the ESC including a plurality of ejection holes for emitting a gas. The pressure measuring apparatus may include a printed circuit board (PCB) substrate having a first surface arranged to face the plurality of ejection holes, the PCB substrate including a plurality of penetration holes each arranged around a corresponding ejection hole of the plurality of ejection holes when viewed in plan view; a first cover disposed on a second surface of the PCB substrate, the first cover including a plurality of discharging holes provided at positions corresponding to the plurality of penetration holes; a second cover arranged between the PCB substrate and the ESC, the second cover including a plurality of first inlet holes, a plurality of second inlet holes, and a plurality of flow paths connecting the plurality of first inlet holes to the plurality of second inlet holes, the plurality of first inlet holes being provided at positions corresponding to the plurality of ejection holes, and the plurality of second inlet holes being provided at positions corresponding to the plurality of penetration holes; and a plurality of pressure sensors attached to the PCB substrate, the plurality of pressure sensors being configured to measure a pressure of a gas ejected from the plurality of ejection holes and moving along the plurality of flow paths.

A pressure measurement system according to an embodiment may include an electrostatic chuck (ESC) including a plurality of ejection holes configured to emit a gas; a pressure measuring apparatus including a printed circuit board (PCB) substrate disposed on the ESC, the PCB substrate including:
a plurality of penetration holes, a cover on a first surface of the PCB substrate and on a second surface of the PCB substrate opposite to the first surface, the cover including a flow path through which the gas is configured to move, and a plurality of pressure sensors configured to measure a pressure of the gas passing through the flow path; and a diagnosis unit configured to determine, based on the measured pressure of the gas, a pressure state of the gas emitted from the plurality of ejection holes.

According to embodiments, the pressure measuring apparatus and the pressure measurement system are provided to measure the pressure of the gas ejected through then ejection hole of then ESC while being placed on the ESC surface and diagnose whether the ejection hole is blocked, thereby it is possible to directly check whether the plurality of ejection holes are blocked, and to identify the position of the ejection hole where the blockage occurred among the plurality of ejection holes by analyzing the measured pressure value with the ESC mounted on an equipment.

### BRIEF DESCRIPTION OF THE DRAWINGS

FIG. 1 is a drawing illustrating a pressure measuring apparatus according to an embodiment.

FIG. 2 and FIG. 3 are views illustrating a PCB substrate in a pressure measuring apparatus according to FIG. 1.

FIG. 4 is a view showing a bottom surface of a second cover in a pressure measuring apparatus according to FIG. 1.

FIG. 5 is a view illustrating an ESC in a pressure measuring apparatus according to FIG. 1.

FIGS. 6, 7A, and 7B are views illustrating a path along which a gas moves in a pressure measuring apparatus according to FIG. 1.

FIG. 8 is a view illustrating a joint structure of a pressure measuring apparatus according to an embodiment.

FIG. 9 is a view illustrating a pressure measurement system according to an embodiment.

### DETAILED DESCRIPTION

The present invention will be described more fully hereinafter with reference to the accompanying drawings, in which embodiments of the invention are shown. As those skilled in the art would realize, the described embodiments may be modified in various different ways, all without departing from the spirit or scope of the present invention.

Descriptions of parts not related to the present invention are omitted, and like reference numerals designate like elements throughout the specification.

Further, since sizes and thicknesses of constituent members shown in the accompanying drawings are arbitrarily given for better understanding and ease of description, the present invention is not limited to the illustrated sizes and thicknesses. In the drawings, the thickness of layers, films, panels, regions, etc., are exaggerated for clarity. In the drawings, for better understanding and ease of description, the thicknesses of some layers and areas are exaggerated.

Throughout this specification and the claims that follow, when it is described that an element is “coupled” to another element, the element may be “directly coupled” to the other element or “electrically coupled” to the other element through a third element. In addition, unless explicitly described to the contrary, the words “comprise” and “include”, and variations such as “comprises” or “comprising” and “includes” or “including”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, in the specification, the phrases “in plan view” and “in a plan view” mean viewing the object portion from the top, and the phrase “in a cross-section” means viewing a cross-section of which the object portion is vertically cut from the side.

An electrostatic chuck (ESC) is a device that uses a static electrical force to hold a substrate flat. In a hole on the upper surface of the ESC, helium gas is ejected toward a wafer to prevent a wafer temperature from rising. Helium gas serves to stabilize the temperature of the ESC and the wafer.

In the holes on the upper surface of the ESC, the phenomenon of the holes becoming blocked by process by-products, etc. often occurs. In this case, a local temperature rise occurs in the wafer, which may lead to process defects such as a wafer damage or changes in an etching rate during an etching process.

Existing methods for determining an ESC hole blockage are indirect methods such as those using a fault detection and classification (FDC). FDC refers to a system that monitors a process taking place in a facility in real time to detect abnormal changes in the facility, and expresses this as an interlock concept. However, FDC has the problem that it is difficult to check whether the hole is blocked while the ESC is mounted on the equipment, and it is difficult to specify the position of the hole where the defect has occurred.

The pressure measuring apparatus 100 and the pressure measurement system 10 according to the present disclosure are intended to improve the above problems, and are intended to enable a direct confirmation of whether a hole is blocked while the ESC is mounted on the equipment, and to specify the position of the hole where a defect has occurred.

Hereinafter, the pressure measuring apparatus 100 and the pressure measurement system 10 according to an embodiment of the present disclosure will be described in more detail with reference to the drawings.

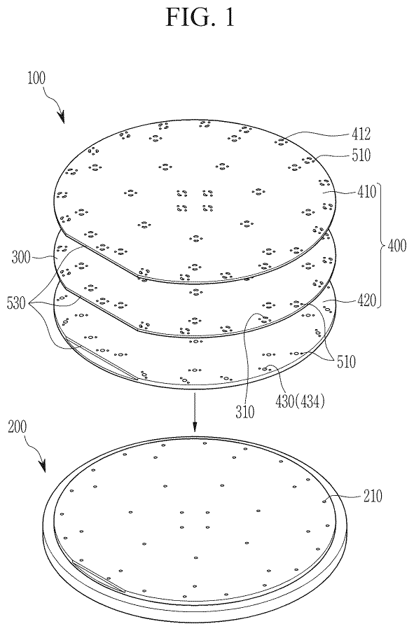

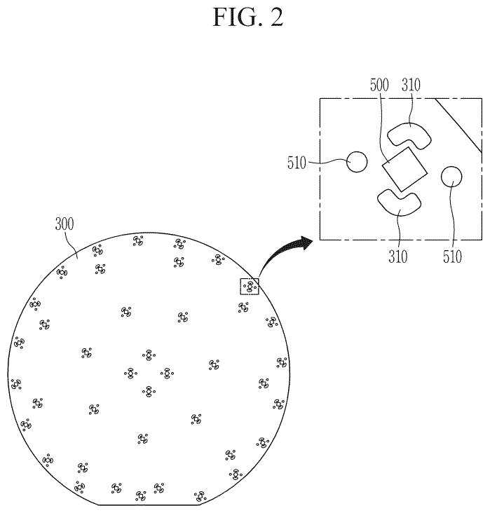

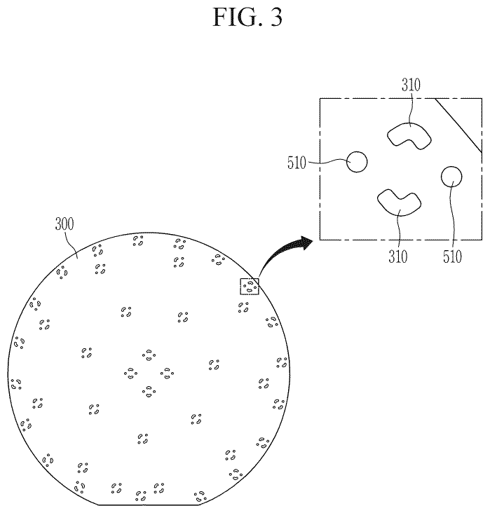

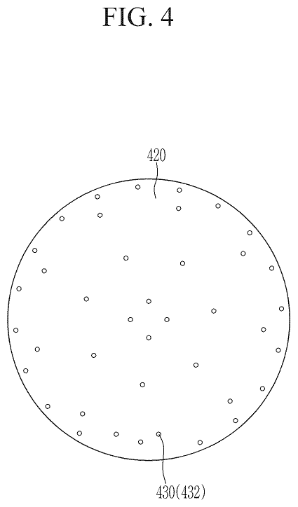

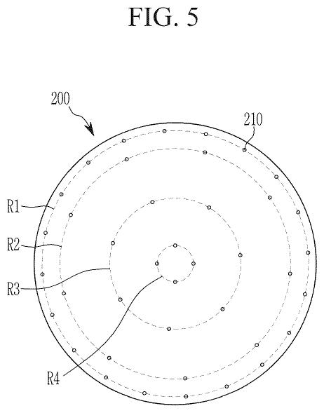

FIG. 1 is a drawing illustrating a pressure measuring apparatus according to an embodiment. FIG. 2 and FIG. 3 are views illustrating a PCB substrate in a pressure measuring apparatus according to FIG. 1. FIG. 4 is a view showing a bottom surface of a second cover in a pressure measuring apparatus according to FIG. 1. FIG. 5 is a view illustrating an ESC in a pressure measuring apparatus according to FIG. 1.

Referring to FIG. 1 to FIG. 5, the pressure measuring apparatus 100 according to an embodiment of the present disclosure may include a PCB substrate 300, a covering part 400, and a pressure sensor 500.

FIG. 1 shows an embodiment in which the pressure measuring apparatus 100 according to the present disclosure is placed on the ESC 200. The pressure measuring apparatus 100 may be placed so that the lower surface of the covering part 400 is in contact with the upper surface of the ESC 200.

First, the ESC 200 may be a structure in which a plurality of ejection holes 210 are arranged so as to be opened toward one side (e.g., toward a first surface) thereof.

The plurality of ejection holes 210 serve to eject a gas such as a cooling gas. The cooling gas may include, for example, helium gas.

Using the cooling gas, for example, when an argon sputter etch process is in progress, a problem may occur where the wafer temperature rises to 100-150° C. due to a collision of argon ions. At this time, by spraying the cooling gas toward the wafer, the heat of the wafer is transferred to the cooling fluid, thereby lowering the temperature of the wafer.

FIG. 2 shows one surface (e.g., a lower surface) of the PCB substrate 300, and is the drawing showing the PCB substrate 300 as seen from below. FIG. 3 shows the other surface (e.g., an upper surface) of the PCB substrate 300, and is the drawing showing the PCB substrate 300 as seen from above.

Referring to FIG. 1 to FIG. 3, the PCB substrate 300 may be placed so that one surface faces the upper surface of the ESC 200. That is, the plurality of ejection holes 210 provided in the ESC 200 and the plurality of ejection holes provided in one surface of the PCB substrate 300 may be arranged to face each other.

The PCB substrate 300 may include a plurality of penetration holes 310. The plurality of penetration holes 310 provided in the PCB substrate 300 may be arranged in proximity to the plurality of ejection holes 210 provided in the ESC 200. For example, the plurality of penetration holes 310 provided in the PCB substrate 300 may be arranged around corresponding ejection holes 210 of the plurality of ejection holes 210 provided in the ESC 200 when viewed in plan view.

The fact that the penetration hole 310 is positioned close to or in proximity to the ejection hole 210 may mean that, when the PCB substrate 300 is positioned on the upper surface of the ESC 200, the penetration holes 310 of the PCB substrate 300 are positioned so as not to overlap the ejection holes 210 of the ESC 200 when viewed in plan view.

The penetration holes 310 are not positioned at the position overlapping the ejection holes 210 when viewed in plan view, but may be positioned close to the overlapping position.

Depending on the embodiment, there may be two or more penetration holes 310 positioned adjacent to each ejection hole 210 among the plurality of ejection holes 210.

Referring to FIG. 1 to FIG. 3, there may be two penetration holes 310 positioned adjacent to each ejection hole 210. For example, an ejection hole 210 is provided at a center between two penetration holes 310 arranged adjacent thereto. However, the number and arrangement positions of the penetration holes 310 are not limited to those shown.

A coupling hole 510 may be formed in the PCB substrate 300. Referring to FIG. 2 and FIG. 3, it may be seen that in addition to two penetration holes 310, two coupling holes 510 are arranged.

As shown in FIG. 1, the coupling holes 510 may be formed in all of the PCB substrate 300, the first cover 410, and the second cover 420.

The PCB substrate 300, the first cover 410, and the second cover 420 may be coupled to each other through respective coupling holes 510 that are arranged to overlap each other along a vertical direction.

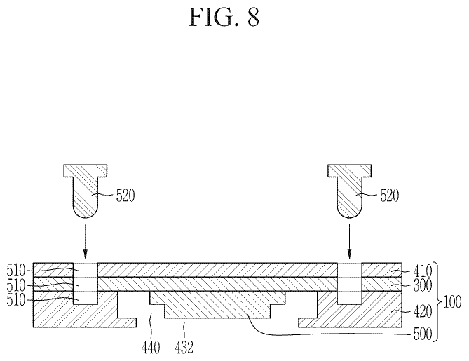

The coupling holes 510 arranged to overlap each other may form a single groove structure (e.g., a single groove), and a bolt or the like may be inserted in each groove to couple the PCB substrate 300, the first cover 410, and the second cover 420 to each other. The coupling structure of the PCB substrate 300, the first cover 410, and the second cover 420 is explained through FIG. 8 below.

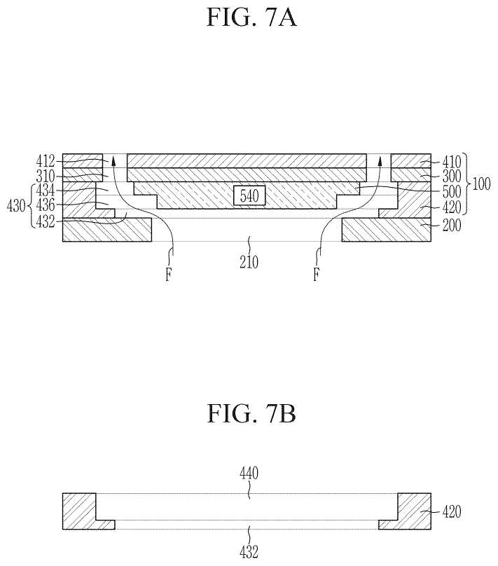

Although the pressure sensor 500 is not visible in FIG. 1, the pressure sensor 500 may be placed between the PCB substrate 300 and the second cover 420 (referring to FIG. 7A).

Referring to FIG. 2 showing one surface (e.g., a lower surface or first surface) of the PCB substrate 300, the plurality of pressure sensors 500 may be provided on one surface of the PCB substrate 300.

The pressure sensor 500 may be a structure attached to one surface of the PCB substrate 300, and according to an embodiment, the pressure sensor 500 may be in a form that is attachable and detachable from the PCB substrate 300.

The pressure sensor 500 may measure the pressure from high vacuum environments below 1 mTorr to an atmospheric pressure environment.

The pressure sensor 500 may be placed in the center surrounded by the penetration hole 310 and the coupling hole 510. For example, the penetration holes 310 and the coupling holes 510 may encircle the pressure sensor 500, or may form a ring around the pressure sensor 500, or may surround the pressure sensor 500, as shown, e.g., in FIG. 2. Referring to the drawing illustrated in FIG. 1, the plurality of pressure sensors 500 may each be placed at a position corresponding to an ejection hole of the plurality of ejection holes 210 of the ESC 200.

According to the present disclosure, the plurality of pressure sensors 500 are characterized in that they are each arranged on a corresponding path through which a gas moves. Specifically, the plurality of pressure sensors 500 are each arranged on corresponding paths along which the gas ejected from the plurality of ejection holes 210 moves to a plurality of flow paths 430, and may measure the pressure of the gas.

The covering part 400 may include a first cover 410 and a second cover 420.

Referring to FIG. 1, the first cover 410 may be arranged on the other surface (e.g., an upper surface or a second surface) of the PCB substrate 300 and may include a plurality of discharging holes 412 provided at positions corresponding to the plurality of penetration holes 310.

The second cover 420 may be placed on one surface (e.g., the lower surface) of the PCB substrate 300. The second cover 420 may be positioned between the PCB substrate 300 and the ESC 200 and may include a plurality of flow paths 430 connecting the plurality of ejection holes 210 of the ESC 200 to the plurality of penetration holes 310 of the PCB substrate 300.

FIG. 4 illustrates the view of the second cover 420 from below.

Referring to the upper surface of the second cover 420 illustrated in FIG. 1, the second cover 420 may include a plurality of flow paths 430 and a plurality of coupling holes 510. FIG. 1 is the drawing showing the upper surface of the flow path 430, showing a second inlet hole (434, referring to FIG. 1 and FIG. 7A) in the flow path 430.

FIG. 4 shows a lower surface of the second cover 420, and the second cover 420 may include the first inlet hole 432 in the flow path 430. Referring to FIG. 1 and FIG. 4 together, the coupling hole 510 included in the second cover 420 may not be a structure that penetrates the entire upper and lower parts, but may be a groove structure in which only the upper part is recessed (see, e.g., FIG. 8).

Looking at the appearance of the second cover 420 illustrated in FIG. 1 and FIG. 4, it may be seen that the second cover 420 includes the flow path 430 having the structure penetrating the upper and lower surfaces thereof, and the coupling hole 510 having the groove structure on the upper surface that does not fully penetrate the second cover 420 from the upper surface to the lower surface thereof. That is, the coupling hole 510 provided in the second cover 420 may have a difference in structure from the structure of the coupling hole 510 provided in the first cover 410 and the PCB substrate 300.

Referring to FIG. 1, the first cover 410, the PCB substrate 300, and the second cover 420 may each further include a guiding part 530 (e.g., a guiding edge). For example, the guiding part 530 of each of the first cover 410, the PCB substrate 300, and the second cover 420 may be a straight, linear edge of each of the first cover 410, the PCB substrate 300, and the second cover 420, which may otherwise have substantially circular edges. See, e.g., FIG. 1.

The guiding part 530 may serve to guide the positions where the PCB substrate 300, the first cover 410, and the second cover 420 are placed so that the plurality of pressure sensors 500 are placed at proper positions corresponding to the plurality of ejection holes 210 of the ESC 200.

Additionally, the guiding part 530 may serve to guide the positions where the PCB substrate 300, the first cover 410, and the second cover 420 are placed so that the gas ejected from the plurality of ejection holes 210 may move efficiently through the flow path 430.

That is, by arranging the guiding parts 530 in a row (e.g., to align with each other along the vertical direction), the gas ejected from the ejection hole 210 of the ESC 200 may be discharged through the second cover 420, the PCB substrate 300, and the first cover 410.

Specifically, the gas ejected from the ejection hole 210 of the ESC 200 flows into the first inlet hole 432 of the second cover 420, sequentially passes through the connection flow path 436 and the second inlet hole 434, passes through the penetration hole 310 of the PCB substrate 300, and is discharged through the discharging hole 412 of the first cover 410. The movement path of the gas is explained again in FIG. 7A.

According to an embodiment, the ESC 200 may be provided with a line (e.g., a guiding edge) corresponding to the guiding part 530 as shown in FIG. 1.

According to the pressure measuring apparatus 100 according to an embodiment described above, the pressure of the emitted gas may be measured to determine whether there is a blockage in the path through which the gas moves.

The element that emits gas is not limited to the ESC 200. For example, other elements may supply the gas such as a shower head, and the determination whether there is the blockage in the path through which the gas moves may be equally applicable to other elements that supply the gas besides the ESC 200.

According to another embodiment, a pressure measuring apparatus 100 is a pressure measuring apparatus 100 disposed on an ESC 200 including a plurality of ejection holes 210 for ejecting a gas, and may include a PCB substrate 300 including one surface (e.g., a first surface or a lower surface) disposed to face the plurality of ejection holes 210 and a plurality of penetration holes 310 corresponding to the plurality of ejection holes 210, a first cover 410 arranged on the other surface (e.g., a second surface or an upper surface) of the PCB substrate 300 and including a plurality of discharging holes 412 provided at positions corresponding to the plurality of penetration holes 310, a second cover 420 disposed between the PCB substrate 300 and the ESC 200 and including a plurality of flow paths 430 having a plurality of first inlet holes 432 provided at positions corresponding to the plurality of ejection holes 210, a plurality of second inlet holes 434 (e.g., outlet holes) provided at positions corresponding to the plurality of penetration holes 310, and a plurality of connection flow paths 436 connecting the plurality of first inlet holes 432 to the plurality of second inlet holes 434, and a plurality of pressure sensors 500 attached to one surface of the PCB substrate 300 to measure the pressure of the gas ejected from a plurality of ejection holes 210 and moving along a plurality of flow paths 430.

FIG. 5 shows the ESC 200 as seen from above, and a plurality of ejection holes 210 may be provided on one surface (top surface) of the ESC 200.

As shown in FIG. 5, one surface of the ESC 200 may have a circular shape. The plurality of ejection holes 210 may be arranged on a concentric circle with different diameters, with the center of the circle as a reference. For example, the plurality of ejection holes 210 may be arranged on different concentric circles having different diameters from each other. The center of the concentric circles may be the same as the center of the circular surface of the ESC 200.

FIG. 5 shows R1, R2, R3, and R4 as the concentric circles with the different diameters on the ESC 200.

Twenty ejection holes 210 may be arranged on the circle R1, nine ejection holes 210 may be arranged on the circle R2, seven ejection holes 210 may be arranged on the circle R3, and four ejection holes 210 may be arranged on the circle R4.

As illustrated, the ejection holes 210 arranged on the same concentric circle may be arranged at equal intervals so that each interval between the ejection holes 210 that are arranged in the same concentric circle are the same.

The ESC 200 illustrated in FIG. 5 is an example, and there may be a plurality of concentric circles with the different diameters, and the number of the ejection holes 210 arranged in each concentric circle is not limited.

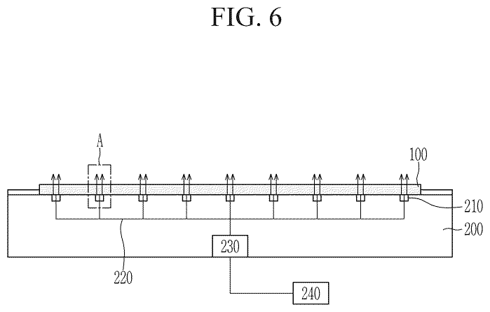

FIG. 6 and FIG. 7A are drawings illustrating the path along which a gas moves in the pressure measuring apparatus according to FIG. 1.

First, FIG. 6 is the drawing showing a side view of the pressure measuring apparatus 100, showing the pressure measuring apparatus 100 placed on the ESC 200.

As shown in FIG. 6, nine ejection holes 210 included in ESC 200 are arranged in the concentric circle of R2 among the plurality of ejection holes 210 shown in FIG. 5. All nine ejection holes 210 are illustrated, and the spacing and shape between the ejection holes 210 are simplified.

The structure of the pressure measuring apparatus 100 is also simplified and illustrated, and the movement path of the gas that is ejected from the ESC 200 and passes through the pressure measuring apparatus 100 is described in detail in FIG. 7A.

The pressure measuring apparatus 100 according to the present disclosure, referring to FIG. 6, may further include a supply flow path 220 connected to the plurality of ejection holes 210 provided in the ESC 200.

The supply flow path 220 is a passage for the gas to move to the plurality of ejection holes 210, and the supply flow path 220 may be arranged within the ESC 200 and may be connected to each ejection hole 210.

Additionally, as shown in FIG. 6, the pressure measuring apparatus 100 may further include a gas supply section 230 connected to the supply flow path 220 and configured to supply the gas to the supply flow path 220. The gas supply section 230 may have a structure connected to the plurality of supply flow paths 220.

According to the embodiment, as shown in FIG. 6, the plurality of supply flow paths 220 connected to the plurality of ejection holes 210 arranged on the concentric circle R2 may be connected to the same gas supply section 230.

That is, in the pressure measuring apparatus 100 according to the present disclosure, all of the ejection holes 210 arranged on the same concentric circle on the ESC 200 may be connected to the same gas supply section 230.

The plurality of ejection holes 210 arranged on the same concentric circle are configured to receive the gas from one gas supply section 230, and the pressure of the gas supplied to the plurality of ejection holes 210 arranged on the same concentric circle may have the same value. In other words, the pressure of the gas ejected from the plurality of ejection holes 210 arranged on the same concentric circle may have the same value.

FIG. 6 shows only the plurality of ejection holes 210 arranged in circle R2, the plurality of supply flow paths 220 connected thereto, and the gas supply section 230 connected to the supply flow path 220. Other concentric circles R1, R3, R4, as well as any other additional concentric circles, may have a similar structure and arrangement to that of the circle R2.

Although not shown in the drawing, the plurality of ejection holes 210 arranged at R1, R2, R3, and R4 may each have a corresponding supply flow path of the plurality of supply flow paths 220 connected thereto, and the gas supply section 230 may supply the gas to each of the supply flow paths 220.

Specifically, a first gas supply section 230 that supplies the gas to the plurality of supply flow paths 220 connected to twenty ejection holes 210 arranged on circle R1, a second gas supply section 230 that supplies the gas to the plurality of supply flow paths 220 connected to nine ejection holes 210 arranged on circle R2, a third gas supply section 230 that supplies the gas to the plurality of supply flow paths 220 connected to seven ejection holes 210 arranged on circle R3, and a fourth gas supply section 230 supplying the gas to the plurality of supply flow paths 220 connected to four ejection holes 210 arranged on circle R4 may be included.

The ESC 200 according to the present disclosure is a structure in which the different gas supply sections 230 are connected to each ejection hole 210 arranged in each concentric circle, and the gas pressure supplied to each ejection hole 210 arranged in each concentric circle may be supplied independently from the gas pressure supplied to other concentric circles.

Accordingly, in the process of measuring the pressure of the gas ejected from the ejection hole 210 of the ESC 200 using the pressure measuring apparatus 100 according to the present disclosure, a method of evaluating the ejection pressure of the gas for each position (each concentric circle) of the plurality of ejection holes 210 may be used.

In FIG. 5, the region where the concentric circle R1 is placed may be referred to as a first region (an outer zone), the region where the concentric circle R2 is placed may be referred to as a second region (a mid-outer zone), the region where the concentric circle R3 is placed may be referred to as a third region (a mid-inner zone), and the region where the concentric circle R4 is placed may be referred to as a fourth region (an inner zone).

The gas may be supplied simultaneously to the plurality of ejection holes 210 arranged in all regions, but the gas may also be supplied only to the ejection holes 210 arranged in the first region by using the gas supply section 230 connected to the ejection holes 210 arranged in the first region.

In this case, the pressure may be measured at the pressure sensor 500 placed in the first region, and by using the measured pressure value, the pressure state of the gas ejected from the ejection hole 210 placed in the first region may be diagnosed first.

Similarly, the pressure state of the gas ejected from the ejection hole 210 in each region of the second region, the third region, and the fourth region may be diagnosed independently.

When measuring the pressure of the gas ejected from all ejection holes 210 in the ESC 200 at once, there is a possibility that the pressure of the gas passing through each ejection hole 210 may be affected due to a problem in the internal structure of the ESC 200.

As explained above, when diagnosing the pressure state of the gas emitted for each region, it is advantageous to measure the gas pressure for each region individually using the pressure measuring apparatus 100 according to the present disclosure to diagnose the problem in the internal structure of the ESC 200.

If it is suspected that some of the ejection holes 210 among the plurality of ejection holes 210 of the ESC 200 are defective, it is preferable to measure the gas pressure by focusing on the region where the ejection holes 210 suspected of being defective are located.

By using the pressure measuring apparatus 100 according to the present disclosure, the position of the ejection hole 210 where the defect has occurred may be identified by isolating and separately measuring only the pressure of the gas ejected from the ejection hole 210 arranged in the certain region, and thus there is an advantage of higher efficiency compared to a method of measuring the pressure of the gas ejected from the entire ejection hole 210 at once.

FIGS. 7A and 7B are an enlarged views of a part A shown in FIG. 6.

FIG. 7A is the drawing to explain the movement path F of the gas passing through each structure of the pressure measuring apparatus 100.

FIG. 7A, as shown in FIG. 1, corresponds to the side shape that the ejection hole 210, the first inlet hole 432, the connection flow path 436, the second inlet hole 434, the penetration hole 310, and the discharging hole 412 are cut out in the state that the pressure measuring apparatus 100 is placed on the ESC 200.

Referring to FIG. 7A, the gas ejected from the ejection hole 210 of the ESC 200 may move sequentially through the flow path 430 of the second cover 420, the penetration hole 310 of the PCB substrate 300, and the discharging hole 412 of the first cover 410.

The flow path 430 provided in the second cover 420 may include a first inlet hole 432, a connection flow path 436, and a second inlet hole 434.

The first inlet hole 432 may be provided at the positions corresponding to the plurality of ejection holes 210 on one surface of the second cover 420. Each ejection hole 210 may be centered about a vertical axis, and each corresponding first inlet hole 432 may be centered about substantially the same vertical axis as shown, e.g., in FIG. 7A. For example, each first inlet hole 432 may be as wide as or wider than the corresponding ejection hole 210 in a horizontal direction.

The second inlet hole 434 may be provided at the position corresponding to the plurality of penetration holes 310 on the other surface of the second cover 420, so that the plurality of second inlet holes 434 may be arranged on the second cover 420.

The connection flow path 436 may connect each first inlet hole 432 among the plurality of first inlet holes 432 to corresponding second inlet holes 434 positioned adjacent to each first inlet hole 432 among the plurality of second inlet hole 434.

The number of the connection flow paths 436 may be equal to the number of the second inlet holes 434.

The structure of the connection flow path 436 is not limited to the shape illustrated in FIG. 7A. The structure of the connection flow path 436 may differ depending on the positions of the first inlet hole 432 and the second inlet hole 434.

FIG. 7B is the drawing showing only the second cover 420 separated from FIG. 7A, and the second cover 420 may be a structure including a groove 440.

As illustrated in FIG. 7B, according to an embodiment, a groove 440, which is a space in which the pressure sensor 500 is placed, may be provided on the other surface (e.g., the upper surface) of the second cover 420. For example, the second cover 420 may include a ring-shaped ridge (e.g., a flange, lip, or rim) on the bottom surface thereof that protrudes into the first inlet hole 432 of the flow path 430. For example, a diameter of the first inlet hole 432 may be less than a diameter of the groove 440.

The pressure sensor 500 may be attached to one surface (e.g., a bottom surface) of the PCB substrate 300 and placed in the groove 440 of the second cover 420, so that the lower surface of the pressure sensor 500 faces the ejection hole 210 of the ESC 200, and may be structured to have a shape corresponding thereto.

The embodiment illustrated in FIG. 7A corresponds to a case where the area forming the lower surface of the pressure sensor 500 is smaller than the area formed by the ejection hole 210 of the ESC 200. In this case, the area of the first inlet hole 432 of the second cover 420 may be larger than the area of the ejection hole 210. In the case of having the layout structure as in FIG. 7A, the gas ejected from the ejection hole 210 may move along the gap (a path) created between the pressure sensor 500, the edge of the ejection hole 210, and the edge of the first inlet hole 432.

According to the present disclosure, the pressure measuring apparatus 100 has the structure that may have the gap (the path) through which the gas may move between the pressure sensor 500, the edge of the ejection hole 210, and the edge of the first inlet hole 432. The lower area of the pressure sensor 500, the size of the ejection hole 210, the size of the first inlet hole 432, and the arrangement position are not otherwise limited.

However, the position must be such that the pressure may be measured by the gas moving from the ejection hole 210 by applying the pressure to the pressure sensor 500.

FIG. 8 is a view illustrating a coupling structure of a pressure measuring apparatus according to an embodiment.

FIG. 8, in the state that the pressure measuring apparatus 100 is disposed on the ESC 200 as shown in FIG. 1, is the cross-section cut in the vertical direction as in FIG. 7A and shows coupling holes 510.

Referring to FIG. 8, the first cover 410, the PCB substrate 300, and the second cover 420 may be provided with the coupling holes 510 at corresponding positions. For example, the coupling holes 510 of the first cover 410, the PCB substrate 300, and the second cover 420 may be aligned along a vertical direction. In the pressure measuring apparatus 100, the first cover 410, the PCB substrate 300, and the second cover 420 may be combined in the same manner as in FIG. 8.

The pressure measuring apparatus 100 may further include a coupling part 520 (e.g., a bolt, screw, cap, dowel, pin, coupling pin or the like) coupled to the coupling hole 510. At this time, the coupling part 520 may be inserted into the coupling hole 510 provided in the first cover 410, the PCB substrate 300, and the second cover 420, so that the first cover 410 and the second cover 420 may be coupled to each other.

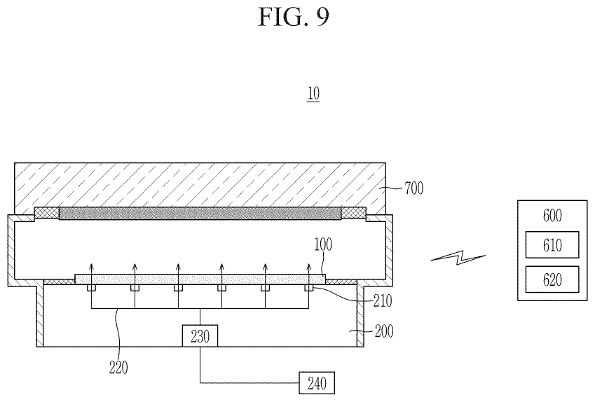

FIG. 9 is a view illustrating a pressure measurement system according to an embodiment.

Referring to FIGS. 7A and 9, a pressure measurement system 10 according to the present disclosure may include an ESC 200 including a plurality of ejection holes 210 emitting a gas, a pressure measuring apparatus 100 including a PCB substrate 300 disposed on the ESC 200 and including a plurality of penetration holes 310 through which the ejected gas moves, a covering part 400 which is placed on one surface and the other surface of the PCB substrate 300 and includes a flow path 430 through which the gas moves, and a plurality of pressure sensors 500 for measuring the pressure of the gas passing through the flow path 430, and a diagnosis unit 600 that diagnoses the pressure state of the gas ejected from a plurality of ejection holes 210 from the pressure measured from a plurality of pressure sensors 500.

The covering part 400 may include a first cover 410 placed on the other surface of the PCB substrate 300 and including a plurality of discharging holes 412, and a second cover 420, positioned between the PCB substrate 300 and the ESC 200 and including a flow path 430 connecting the plurality of ejection holes 210 and the plurality of penetration holes 310.

The plurality of discharging holes 412 may be arranged on the other surface of the PCB substrate 300 and provided at positions corresponding to the plurality of penetration holes 310.

The flow path 430 may include a first inlet hole 432, a second inlet hole 434, and a connection flow path 436 connecting the first inlet hole 432 and the second inlet hole 434.

The first inlet hole 432 may be provided at the positions corresponding to the plurality of ejection holes 210 on one surface of the second cover 420. The second inlet hole 434 may be provided at the positions corresponding to the plurality of penetration holes 310 on the other surface of the second cover 420. The connection flow path 436 may be provided in plural, connecting each first inlet hole 432 among the plurality of first inlet holes 432 and the plurality of second inlet holes 434 that are positioned proximate to each first inlet hole 432 among the plurality of second inlet holes 434.

The pressure measurement system 10 may further include a supply flow path 220, which is connected to the plurality of ejection holes 210 and is a passage for the gas moving to the plurality of ejection holes 210, a gas supply section 230 for supplying the gas to the supply flow path 220, and a pressure adjustor 240 (e.g., a controller) that controls the pressure of the supplied gas according to the pressure status of the gas diagnosed in the diagnosis unit 600.

The controller may be a computer (or several interconnected computers) and may include, for example, one or more processors configured by software, such as a CPU (Central Processing Unit), GPU (graphics processor), controller, etc., forming various functional modules of the computer. The computer may be a general purpose computer or may be dedicated hardware or firmware (e.g., an electronic or optical circuit, such as application-specific hardware, such as, for example, a digital signal processor (DSP) or a field-programmable gate array (FPGA)). A computer may be configured from several interconnected computers. Each functional module (or unit) described herein may comprise a separate computer, or some or all of the functional module (or unit) may be comprised of and share the hardware of the same computer. Connections and interactions between the units described herein may be hardwired and/or in the form of data (e.g., as data stored in and retrieved from memory of the computer, such as a register, buffer, cache, storage drive, etc., such as part of an application programming interface (API)). The functional modules (or units) of the controller may each correspond to a separate segment or segments of software (e.g., a subroutine) which configure the computer of the controller, and/or may correspond to segment(s) of software that also correspond to one or more other functional modules (or units) described herein (e.g., the functional modules (or units) may share certain segment(s) of software or be embodied by the same segment(s) of software). As is understood, “software” refers to prescribed rules to operate a computer, such as code or script. A storage may also be included and may comprise conventional memory of a computer, such as a hard drive (which may be a solid state drive, DRAM, NAND flash memory, etc.). Conventional computer user interfaces may also be included such as a keyboard, mouse, trackpad, touchscreen, etc.

As is traditional in the field of the disclosed technology, features and embodiments are described, and illustrated in the drawings, in terms of functional blocks, units, and/or modules. Those skilled in the art will appreciate that these blocks, units, and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or similar, they may be programmed using software (e.g., microcode) to perform various functions discussed herein and may optionally be driven by firmware and/or software. Alternatively, each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of the embodiments may be physically separated into two or more interacting and discrete blocks, units, and/or modules without departing from the scope of the inventive concepts. Further, the blocks, units, and/or modules of the embodiments may be physically combined into more complex blocks, units, and/or modules without departing from the scope of the inventive concepts.

The pressure measuring apparatus 100 and the ESC 200 included in the pressure measurement system 10 according to FIG. 9 are the same as the pressure measuring apparatus 100 and the ESC 200 described above, so the detailed description thereof will be omitted.

The diagnosis unit 600 may further include an image section 610 that displays information (e.g., the pressure value) measured by the pressure sensor 500 as an image.

The pressure sensor 500 according to the present disclosure, as shown in FIG. 7A, may further include a transmitter 540 that transmits the measured pressure value to the diagnosis unit 600.

The diagnosis unit 600 may include a receiver 620 for receiving transmitted data (e.g., the pressure value). The diagnosis unit 600 may receive the pressure value of the gas passing through each ejection hole 210 measured by the pressure sensor 500.

According to an embodiment, the diagnosis unit 600 may receive the pressure value measured by the pressure sensor 500 in real time and diagnose the pressure distribution.

The image section 610 of the diagnosis unit 600 may display the pressure value of the gas emitted from the ESC 200 as an image by using the received pressure value.

The image section 610 may display the image of the ESC 200 and the plurality of ejection holes 210 included in the ESC 200 on a monitor. Additionally, the pressure value of the gas ejected from the plurality of ejection holes 210 may be matched and displayed on the ESC 200.

According to an embodiment, as described in FIG. 5, the image section 610 may also be displayed to facilitate a comparison of pressure distributions in each region of the ESC 200.

The user may check at a glance the pressure distribution ejected from the plurality of ejection holes 210 of the ESC 200 by using the image displayed on the monitor. As a result, it is possible to determine whether a blockage has occurred in the plurality of ejection holes 210 from the difference in the pressure value of the gas ejected from the plurality of ejection holes 210.

The process using the ESC 200 described above may be performed in the chamber 700, which has a vacuum inside. Using a conventional method, it was only possible to diagnose whether the ejection hole 210 of the ESC 200 was blocked by pulling the ESC 200 from chamber 700.

In contrast, the pressure measuring apparatus 100 and the pressure measurement system 10 according to the present disclosure are significant in that they enable direct confirmation of the clogging of the ejection hole 210 while the ESC 200 is mounted on an equipment, and also enable identification of the position of the ejection hole 210 where the defect has occurred.

Additionally, the pressure measuring apparatus 100 according to the present disclosure includes the guiding part 530 (referring to FIG. 1), and the user may also manually mount the pressure measuring apparatus 100 on the ESC 200 by utilizing the guiding part 530. Additionally, the pressure measuring apparatus 100 may be transported into the chamber 700 by using, e.g., a transport robot and placed on the ESC 200.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A pressure measuring apparatus comprising:
a printed circuit board (PCB) substrate having a first surface facing an electrostatic chuck (ESC), the ESC having a plurality of ejection holes, and the PCB substrate including a plurality of penetration holes;
a first cover disposed on a second surface of the PCB substrate, the first cover including a plurality of discharging holes provided at positions corresponding to the plurality of penetration holes;
a second cover positioned between the PCB substrate and the ESC, the second cover including a plurality of flow paths connecting the plurality of ejection holes to the plurality of penetration holes; and
a plurality of pressure sensors disposed between the PCB substrate and the second cover.

2. The pressure measuring apparatus of claim 1, wherein:
each of the plurality of pressure sensors is positioned to correspond to a respective ejection hole of the plurality of ejection holes.

3. The pressure measuring apparatus of claim 2, wherein:
the plurality of pressure sensors are configured to measure a pressure of a gas ejected from the plurality of ejection holes and traveling through the plurality of flow paths.

4. The pressure measuring apparatus of claim 1, wherein:
each of the plurality of penetration holes is arranged around a corresponding ejection hole of the plurality of ejection holes when viewed in plan view.

5. The pressure measuring apparatus of claim 4, wherein:
each ejection hole of the plurality of ejection holes is in fluid connection with two or more penetration holes of the plurality of penetration holes.

6. The pressure measuring apparatus of claim 1, wherein the flow path includes:
a plurality of first inlet holes each provided at a position corresponding to an ejection hole of the plurality of ejection holes on a first surface of the second cover,
a plurality of second penetration holes each provided at a position corresponding to a penetration hole of the plurality of penetration holes on a second surface of the second cover opposite to the first surface of the second cover, and
a plurality of connection flow paths connecting each first inlet hole among the plurality of first inlet holes to a corresponding second inlet hole of the plurality of second inlet holes.

7. The pressure measuring apparatus of claim 6, wherein:
the second surface of the second cover includes a groove in which the pressure sensor is positioned.

8. The pressure measuring apparatus of claim 1, wherein:
the first cover, the PCB substrate and the second cover each include coupling holes at mutually corresponding positions.

9. The pressure measuring apparatus of claim 8,further comprising:
a coupling pin coupled to each of the coupling holes,
wherein the coupling pin couples the first cover to the second cover.

10. A pressure measuring apparatus disposed on an electrostatic chuck (ESC), the ESC including a plurality of ejection holes for emitting a gas, the pressure measuring apparatus comprising:
a printed circuit board (PCB) substrate having a first surface arranged to face the plurality of ejection holes, the PCB substrate including a plurality of penetration holes each arranged around a corresponding ejection hole of the plurality of ejection holes when viewed in plan view;
a first cover disposed on a second surface of the PCB substrate, the first cover including a plurality of discharging holes provided at positions corresponding to the plurality of penetration holes;
a second cover arranged between the PCB substrate and the ESC, the second cover including a plurality of first inlet holes, a plurality of second inlet holes, and a plurality of flow paths connecting the plurality of first inlet holes to the plurality of second inlet holes, the plurality of first inlet holes being provided at positions corresponding to the plurality of ejection holes, and the plurality of second inlet holes being provided at positions corresponding to the plurality of penetration holes; and
a plurality of pressure sensors attached to the PCB substrate, the plurality of pressure sensors being configured to measure a pressure of a gas ejected from the plurality of ejection holes and moving along the plurality of flow paths.

11. The pressure measuring apparatus of claim 10, wherein:
the pressure sensor is attachable to and detachable from the PCB substrate.

12. The pressure measuring apparatus of claim 10, wherein:
each of the first cover, the PCB substrate, and the second cover further includes:
a guiding edge configured to guide the positions at which the PCB substrate, the first cover, and the second cover are arranged so that the ejected gas moves through the flow path.

13. A pressure measurement system comprising:
an electrostatic chuck (ESC) including a plurality of ejection holes configured to emit a gas;
a pressure measuring apparatus including a printed circuit board (PCB) substrate disposed on the ESC, the PCB substrate including:
a plurality of penetration holes,
a cover on a first surface of the PCB substrate and on a second surface of the PCB substrate opposite to the first surface, the cover including a flow path through which the gas is configured to move, and
a plurality of pressure sensors configured to measure a pressure of the gas passing through the flow path; and
a diagnosis unit configured to determine, based on the measured pressure of the gas, a pressure state of the gas emitted from the plurality of ejection holes.

14. The pressure measurement system of claim 13, wherein:
a first surface of the ESC has a circular shape, and
the plurality of ejection holes of the ESC are arranged along a plurality of concentric circles having different diameters about a center of the circular shape of the first surface of the ESC.

15. The pressure measurement system of claim 13, wherein the cover includes:
a first cover disposed on the second surface of the PCB substrate, the first cover including a plurality of discharging holes; and
a second cover positioned between the PCB substrate and the ESC, the second cover including the flow path connecting the plurality of ejection holes to the plurality of penetration holes.

16. The pressure measurement system of claim 15, wherein:
the plurality of discharging holes are arranged on the second surface of the PCB substrate and are provided at positions corresponding to the plurality of penetration holes of the ESC.

17. The pressure measurement system of claim 15, further comprising:
a supply flow path that is connected to the plurality of ejection holes; and
a gas supply configured to supply the gas to the supply flow path.

18. The pressure measurement system of claim 17, further comprising:
a controller configured to adjust a pressure of the gas supplied by the gas supply according to the pressure state of the gas determined by the diagnosis section.

19. The pressure measurement system of claim 13, wherein:
the diagnosis unit further includes an image section configured to display the measured pressure of the gas passing through the flow path.

20. The pressure measurement system of claim 19, wherein:
each pressure sensor of the plurality of pressure sensors includes a transmitter configured to transmit the measured pressure to the diagnosis unit, and
the diagnosis unit includes a receiver configured to receive the measured pressure from each pressure sensor of the plurality of pressure sensors.
